(19) United States
(12) Patent Application Publication
(10) Pub. No.: US 2016/0043319 A1
(43) Pub. Date: Feb. 11, 2016

(54) ACTIVELY-ALIGNED FINE METAL MASK

(71) Applicant: APPLIED MATERIALS, INC., Santa Clara, CA (US)

(72) Inventors: John M. WHITE, Hayward, CA (US); Robert Jan VISSER, Menlo Park, CA (US); Dieter HAAS, San Jose, CA (US); Tommaso VERCESI, Verona (IT); Andreas LOPP, Freigericht-Somborn (DE)

(73) Assignee: Applied Materials, Inc., Santa Clara, CA (US)

(21) Appl. No.: 14/782,500

(22) PCT Filed: Apr. 21, 2014
(86) PCT No.: PCT/US2014/034799

§ 371 Date: Oct. 5, 2015

Related U.S. Application Data
(60) Provisional application No. 61/872,336, filed on Aug. 30, 2013.
(60) Provisional application No. 61/814,764, filed on Apr. 22, 2013.

(51) Int. Cl. H01L 51/00; H01L 51/56; G02B 26/02

(52) U.S. Cl. CPC H01L 51/0012; G02B 26/02; H01L 51/56

(57) ABSTRACT

The embodiments described herein generally relate to active alignment of a fine metal mask. The fine metal mask is connected with a frame through a plurality of microactuators. The microactuators can act on the fine metal mask to stretch the mask, reposition the mask or both. In this way, the position and size of the fine metal mask can be maintained in relation to the substrate.

### BACKGROUND OF THE INVENTION

1. Field of the Invention

Embodiments disclosed herein generally relate to mask alignment. More specifically, embodiments disclosed herein generally relate to active mask alignment for opto-electronic devices.

2. Description of the Related Art

Opto-electronic devices that make use of organic materials are becoming increasingly desirable for a number of reasons. Many of the materials used to make such devices are relatively inexpensive, so organic opto-electronic devices have the potential for cost advantages over inorganic devices. As well, the inherent properties of organic materials, such as their flexibility, may be advantageous for particular applications such as for deposition or formation on flexible substrates. Examples of organic opto-electronic devices include organic light emitting devices (OLEDs), organic phototransistors, organic photovoltaic cells, and organic photodetectors.

For OLEDs, the organic materials are believed to have performance advantages over conventional materials. For example, the wavelength at which an organic emissive layer emits light may generally be readily tuned with appropriate dopants. OLEDs make use of thin organic films that emit light when voltage is applied across the device. OLEDs are becoming an increasingly interesting technology for use in applications such as flat panel displays, illumination, and backlighting.

Prior to and during evaporative deposition of OLED materials, small differences from run to run and changes in temperature during deposition cause the fine metal mask to be or become misaligned with any pre-existing patterns on a substrate. To date these small temperature variations and changes during processing have limited the use of shadow masks for evaporative patterning to relatively small substrates and relatively larger defined features.

One solution has been to do very precise alignment of masks to substrates, maintain deposition temperatures as low and constant as possible during processing and to use mask materials having low thermal coefficient of expansion. This deposition technique has been done for many years and it has reached its limits.

Another possible solution is Small Mask Scanning (SMS). SMS involves the use of a mask which is smaller than the whole substrate or display; and which is scanned relative to the substrate, whereby the mask is used to deposit strips of R, G and B material. This technique has many problems, due to the fact that there must be a clearance maintained between the substrate and the mask during deposition, which leads to cross contamination among the R, G and B emissive materials. Further, SMS can create defects due to scratching, which results from the desire to keep the running clearance as small as possible during the scanning to avoid the above described cross contamination.

Thus, there is a continuing need for improved masks and masking techniques in the formation of opto-electronic devices.

### SUMMARY OF THE INVENTION

The embodiments described herein generally relate to active mask alignment for opto-electronic devices.

In one embodiment, a device can include a frame disposed with a process chamber, a fine metal mask with a connection plate and a pattern, and a plurality of actuators connecting the fine metal mask with the frame wherein the actuators act on the fine metal mask to stretch the fine metal mask, reposition the fine metal mask or combinations thereof.

In another embodiment, a masking device can include a fine metal mask having a pattern and a connection plate surrounding the pattern and a plurality of microactuators coupled to the fine metal mask.

In another embodiment, a masking device can include a frame comprising a plurality of frame openings formed on at least one side of the frame, a fine metal mask, and a plurality of actuators coupled to the frame and the fine metal mask. The fine metal mask can include at least one pattern, a connection plate formed on at least one side of the pattern and one or more mask openings therethrough.

In another embodiment, a method of adjusting a mask can include positioning a substrate in a processing chamber having a fine metal mask disposed therein, determining an alignment of at least a portion of the fine metal mask relative to the substrate using one or more alignment marks and changing the alignment of the at least a portion of the fine metal mask in response to the determining. The fine metal mask can include a pattern and one or more alignment marks.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A and 1B depict a portion of a process chamber with a fine metal mask according to one embodiment;

FIGS. 2-7 depict a top view of the mask assembly according to one or more embodiments;

FIG. 8 depicts a dynamic strip fine metal mask according to one embodiment;

FIG. 9 depicts a dynamic fine metal mask according to one or more embodiments; and

FIG. 10 is a block diagram of a method of aligning a fine metal mask according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments disclosed herein generally relate to actively aligning fine metal masks. A fine metal mask refers to masks that may be used during deposition of materials onto a substrate. The fine metal mask may be used to form features having a pattern resolution smaller than the entire active (light emitting) area of the substrate. Typically, the fine metal mask has one dimension that is of the order of the dimensions of a portion of the sub-pixels (usually of one color) that are to be disposed on the substrate. The fine metal mask is thereby typically utilized for the deposition of the emissive layer of an organic device, where the differing colors of the display are each deposited separately through the fine metal mask and designed to only allow deposition on a portion of the active OLEDs present in the display (e.g., the fine metal mask through which only the red emissive layer is deposited, another fine metal mask through which only the green emissive layer is deposited, etc.).

During the deposition process, both the substrate and the fine metal mask are heated and thus both the substrate and the fine metal mask expand to some degree. As the substrate and the fine metal mask expand, the alignment of the fine metal mask with relation to the substrate can be offset. By positioning the fine metal mask in connection with a rigid frame using microactuators, the fine metal mask can be actively aligned based on expected or actual expansion of the substrate during processing. The active alignment can be determined mathematically (such as by using known expansion rates) or the alignment change can be empirically determined. The embodiments disclosed herein are more clearly described with reference to the figures below.

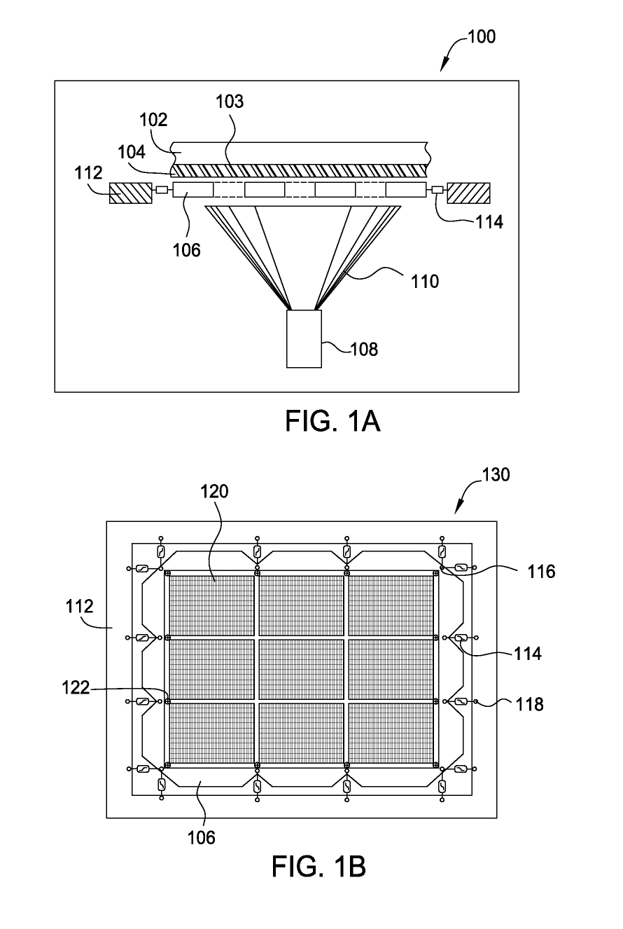

FIGS. 1A and 1B depict a portion of a process chamber 100 with a fine metal mask 106 according to one embodiment. The process chamber 100 can be a standard process chamber adapted for use with the described embodiments. In one embodiment, the process chamber 100 can be a chamber available from AKT America, Inc., a subsidiary of Applied Materials, Inc., Santa Clara, Calif. It is to be understood that the embodiments discussed herein may be practiced on other chambers, including those chambers sold by other manufacturers.

A substrate 102 can be positioned in the process chamber 100 in connection with an electrostatic chuck (not shown). The substrate 102 can be a substrate suitable for deposition of an OLED. In one embodiment, the substrate 102 is substantially composed of glass. The substrate can be of a broad range of dimensions (e.g. length, width, shape, thickness, etc). In one embodiment, the substrate is approximately 1 meter long and 1 meter wide. In this embodiment, the substrate 102 is depicted with a cathode 104 formed over the lower surface 103. The cathode 104 may comprise indium tin oxide (ITO). In other embodiments, the cathode 104 is discontinuous and is formed on the substrate in conjunction with the formation of the OLED layers (not shown).

A source 108 is positioned under the substrate 102 and the cathode 104. Generally, the source 108 can be a source boat or other container or receptacle capable of producing a deposition gas 110. The deposition gas 110 can be configured to deposit further layers over the cathode 104, such as an emission layer, a hole transport layer, a color change layer or further layers (not shown) as required or desired for the formation of the OLED structure. In one embodiment, the source 108 produces a deposition gas 110 to form a white emission layer (not shown) over the cathode 104 and a color change layer over the white emission layer. In another embodiment, the source 108 produces a deposition gas 110 to form a color emission layer (not shown) over the cathode 104. One or more additional layers may be formed over the cathode 104, such as an electron transport layer (not shown).

Positioned between the substrate 102 and the source 108 is a fine metal mask 106. It is understood that the fine metal mask 106 is not depicted to scale and may be smaller or larger than shown, in length, width or height with comparison to the related structures. The fine metal mask 106 can be at least partially composed of one or more magnetic or non-magnetic metals. Suitable materials for the fine metal mask 106 or components thereof include, but are not limited to INVAR (64FeNi), ASTM Grade 5 titanium (Ti-6Al-4V), titanium, aluminum, molybdenum, copper, 440 stainless steel, HASTELLOY® alloy C-276, nickel, chrome-molybdenum steel, 304 stainless steel, other iron containing compositions, or combinations thereof.

The fine metal mask 106 can be of a size and shape which allows for coverage of at least a portion of the substrate. In one embodiment, the fine metal mask 106 is from 2 meters and 3 meters in length and from 1.5 meters to 2 meters in height. The fine metal mask 106 can have a thickness of less than 200 um, such as 100 um. In one embodiment, the fine metal mask is less than 100 um. The fine metal mask 106 can be positioned in a frame 112. Further, the fine metal mask 106 can be connected to a frame 112 using one or more microactuators 114. The frame 112 can be composed of a material similar to that of the fine metal mask 106. The frame 112 can have a rigidity which allows the microactuators 114 to act on the fine metal mask 106 without deformation or with limited deformation of the frame 112. In one embodiment, the frame 112 is composed of INVAR. Though only two microactuators 114 can be seen from this view, one or more microactuators 114 can be used for positioning the fine metal mask 106 within the frame 112.

The fine metal mask 106 is placed into a frame 112. As stated above, the frame 112 is sufficiently stiffer than the fine metal mask 106 to provide resistance for the fine metal mask 106. The microactuators 114, shown in FIG. 1B as sixteen (16) microactuators 114, can be each connected to mask opening 116 and a frame opening 118 to create a mask assembly 130. The microactuators 114, though described as actuators, can be any device for applying an amount of force which can be used to either align or stretch the fine metal mask 106. Further, the number of microactuators 114 is not intended to be limiting, as there may be more or fewer microactuators 114 based on the needs of the user.

As well, the fine metal mask 106 may also be directly attached to the frame 112 without the use of a microactuator 114 at one or more points. In the embodiments described above, the microactuators 114 are shown in connection with the fine metal mask 106 and the frame 112 such that there are two microactuators 114 formed bilaterally across from one another, as defined by a bisecting line in the fine metal mask 106 and/or the frame 112. In this embodiment, the microactuators 114 may be positioned in a non-uniform fashion, a bilateral fashion. In a rectangular fine metal mask 106 connected with an equivalent frame 112, one side of the fine metal mask 106 may be attached to the frame 112 by welding or other semi-permanent attachment process, wherein the other three sides may be attached using a plurality of microactuators 114. The number and positioning of microactuators 114 used at each side can be asymmetrical with regards to positioning, quantity or combinations thereof. Though this example describes only one side of the fine metal mask 106 as being semi-permanently attached, one or more sides or portions of sides may be similarly attached, so long as microactuators are incorporated into at least one portion of the connection between the fine metal mask 106 and the frame 112.

The mask opening 116 and the frame opening 118 are depicted as holes in the fine metal mask 106 and the frame 112 respectively. However, other connections may be used, such as a hook or bolt attaching the microactuator 114 or welding the microactuator 114 to the frame 112, the fine metal mask 106 or both. Further, the mask opening 116 and the frame opening 118 are depicted in this embodiment as being in line with the streets of the fine metal mask. However, this design is not to be considered limiting and other positions for the mask opening 116 and the frame opening 118 which allow for uniform or directional transmission of force to the fine metal mask 106 are envisioned.

In operation, the microactuators 114 can provide tensioning so as to bring the fine metal mask 106 and pattern-defining features 120 to the final desired size and position relative to the substrate 102. The mask assembly 130, which includes the fine metal mask 106 and frame 112, would then be loaded into the process chamber 100. Once properly positioned, the process chamber 100 is then pumped down, wherein the temperature is stabilized and made ready to receive the substrate 102. The substrate 102 can then be brought into the process chamber 100 and the alignment marks 122 on the fine metal mask 106 brought into alignment with corresponding features on the substrate 102. Finally as deposition would begin and proceed, the temperature changes to the fine metal mask 106 and/or the substrate 102 during deposition can be compensated for through a computer-controlled algorithm in control of the microactuators 114. The microactuators 114 can be configured to either continuously, with a specific frequency or sporadically to align the fine metal mask in relation to alignment data derived from alignment marks 122. Thus, the microactuators 114 can maintain the proper desired alignment and size of the fine metal mask 106 as correlated with the features on the substrate 102.

In further embodiments, the microactuators 114 can provide tension which is localized to the current deposition area on the substrate 102. Since the position of the evaporation head/nozzles (the source 108) in a multi-point-source array or line-source configuration is known during the scan, the microactuators 114 of the fine metal mask 106 can adjust such that the fine metal mask 106 is properly aligned over at least the affected area of the substrate 102. In this embodiment, it is believed to be only necessary to maintain alignment instantaneously and locally at the location of the head. More localized control of the alignment of the fine metal mask 106 can lessen the challenge of maintaining mask to substrate alignment.

Without intending to be bound by theory, it is believed that by reducing the constant force applied to the frame 112 by the fine metal mask 106, the frame 112 can be made lighter than standard frames. Standard fine metal masks are formed from a piece of low thermal expansion sheet metal which is stretched and then attached in a stretched state to a heavy frame. The heavy frame is generally required to maintain the high stretching of the fine metal mask and can be on the order of thousands of pounds. Thus, the heavy frame cannot be easily moved or cleaned. In the described embodiments, prestretching is minimized and the mask is stretched to accommodate for misalignment or thermal expansion. Thus, through the described embodiments, the required strength of the frame and the weight required for the frame can be decreased.

The microactuators 114 are described as being capable of bi-directional movement. However, the microactuators 114 useable with embodiments described herein can be unidirectional, where the microactuator 114 provides either pushing or pulling force such that the tension of the fine metal mask 106 is appropriately adjusted. When using microactuators 114 which only pull, the fine metal mask 106 can be tensioned according to the expansion of the fine metal mask 106 during processing. When using microactuators 114 that only push, the fine metal mask 106 can be controlled using the microactuators 114 by appropriately directing the force necessary for reaching the proper tension, such as by either pretensioning the fine metal mask 106 or by redirecting the force of the microactuators 114. In the case of redirecting the force, the microactuators 114 push on a device in connection with the fine metal mask 106 such that the push force becomes a pull force. In one example, the microactuator 114 expands against an arm (not shown) which has a central pivot point (not shown). A cable (not shown) is connected with the fine metal mask 106 and the arm on a side opposite of the microactuator 114. The push force from the microactuator 114 is transferred through the arm as the arm pivots at the pivot point to pull the cable and tension the fine metal mask 106. A variety of embodiments are envisioned for redirecting the force of the microactuator 114. In the case of pretensioning, if we assume that X is the tension required for proper positioning of the fine metal mask 106, the fine metal mask would be pretensioned to a tension of X+Y, where Y is an additional tension beyond the expected relaxation from temperature change in the fine metal mask. Y may also be defined as the combination of the relaxation which is provided by both the temperature change in the fine metal mask 106 and the pushing movement of the microactuators 114. When the substrate is cold, the Y is entirely provided by the microactuators 114. As the substrate heats up, the microactuators 114 slowly reduce the amount of force applied to compensate for the relaxation from the temperature increase.

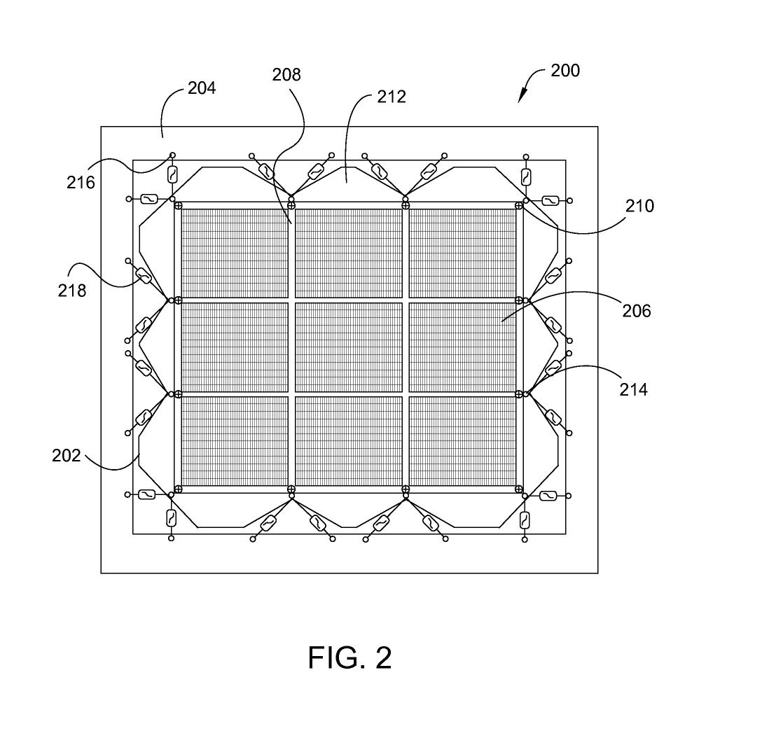

FIGS. 2-7 depict a top view of mask assemblies according to one or more embodiments. Though each of the embodiments are described as being generally uniform with various symmetrical components, it is understood that the number and position of components as described may be moved, adjusted or reoriented without diverging from the descriptions herein. Further, the embodiments may be combined as needed or desired.

FIG. 2 depicts a mask assembly according to one embodiment. The mask assembly 200 includes a fine metal mask 202 connected to a frame 204. The fine metal mask 202 has a pattern 206, depicted here as formed in the center of the fine metal mask 202. A plurality of streets 208 are formed in and around the pattern 206. The plurality of streets 208 have one or more alignment marks 210 formed therein. Surrounding the pattern 206 and the streets 208 can be a connection plate 212 with a plurality of mask openings 214. The connection plate 212 of the fine metal mask 202 can include a variety of shapes and sizes to allow for movement of the fine metal mask 202 within the frame 204. The components of the fine metal mask 202 described above can all be of the same composition, such as a fine metal mask 202 cut from a single piece of sheet metal. In another embodiment, one or more of the components or portions of a single component of the fine metal mask 202 can be composed of separate materials.

Formed in the frame 204 is a plurality of frame openings 216. The frame 204 can be connected with the fine metal mask 202 using a plurality of microactuators 218. Depicted here, the frame 204 and the fine metal mask 202 are connected using two microactuators 218 at each mask opening 214. The microactuators 218 are connected individually to the frame 204, thus allowing for the application of force at an angle. In this example, the angle is approximately 45 degrees and approximately 315 degrees as measured from the mask opening 214. The microactuators 218 are depicted here as being coplanar with the fine metal mask 202 and the frame 204. However, the microactuators can be positioned in any position and orientation, including different planes on a three dimensional depiction, which allows for adjustment to the fine metal mask 202.

Without intending to be bound by theory, it is believed that applying force at an angle will allow the simultaneous repositioning and stretching of the fine metal mask 202. During expansion, such as that which occurs during deposition, the fine metal mask 202 can shift both in position and size, with relation to the substrate 102. Thus by allowing simultaneous accommodation of both size and position, subsequent deposition through the fine metal mask 202 can be better controlled.

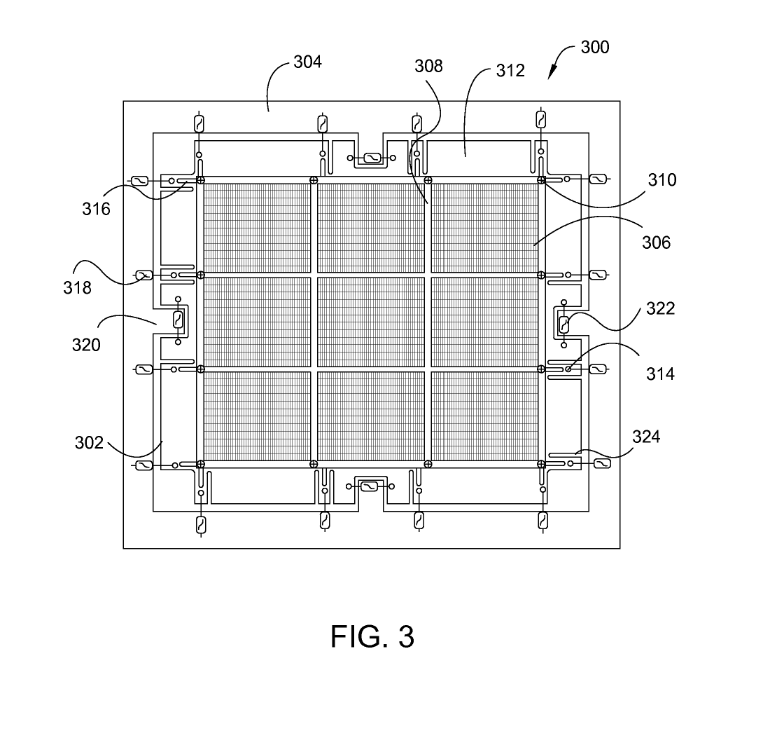

FIG. 3 depicts a mask assembly according to another embodiment. The mask assembly 300 includes a fine metal mask 302 connected to a frame 304. As described with reference to FIG. 2, the fine metal mask 302 has a pattern 306 with a plurality of streets 308 including one or more alignment marks 310 formed therein. Surrounding the pattern 306 and the streets 308 can be a connection plate 312 with a plurality of mask openings 314. The connection plate 312 of the fine metal mask 302 can include a plurality of notches 316 formed between each of the mask openings 314 and the pattern 306. The fine metal mask 302 can further have one or more slits 324 formed in the connection plate 312.

Connected with the frame 304, is a plurality of microactuators 318. The frame 304 can be connected with the fine metal mask 302 using a plurality of microactuators 318. Depicted here, the frame 304 and the fine metal mask 302 are connected using one of the microactuators 318 at each mask opening 314. The microactuators 318 are connected individually to the frame 304, thus allowing for the application of force in a linear fashion. The frame 304 can have a frame peninsula 320 formed thereon. The frame peninsula 320 can be formed in the approximate center of a side of the frame 304. The frame peninsula 320 can rest in an opening in the connection plate 312. The frame peninsula can allow the frame 304 to connect with a center microactuator 322. The center microactuator 322 can be connected to the fine metal mask 302 at two points, such that the center microactuator 322 can apply force to the fine metal mask 302 in two directions.

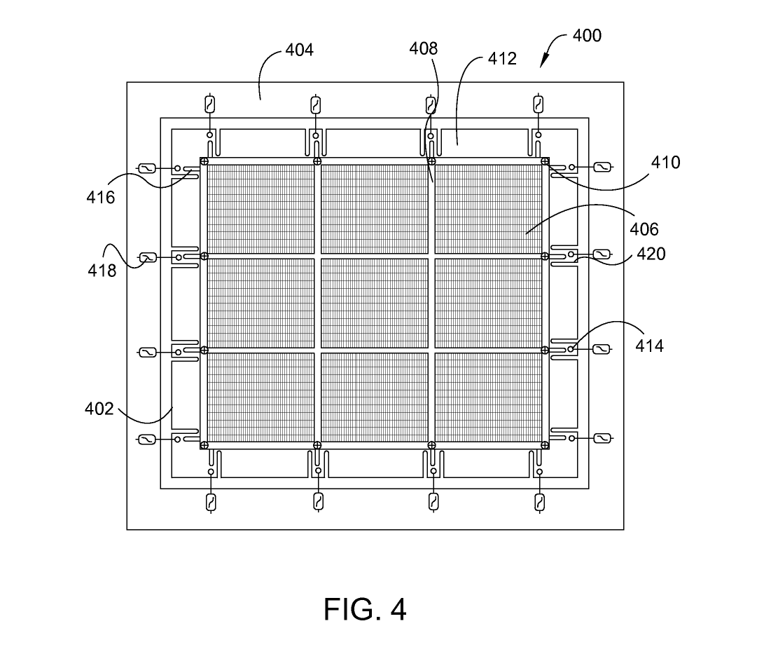

FIG. 4 depicts a mask assembly 400 according to another embodiment. The mask assembly 400 includes fine metal mask 402 and a frame 404. As described above, the fine metal mask 402 has a pattern 406, one or more streets 408 and a plurality of alignment marks 410 formed therein. In this embodiment, a connection plate 412 is formed around the pattern 406 with one or more peninsulas 420 formed therein. The peninsulas 420 each have at least one notch 416 formed therein. The peninsulas 420 and the notches 416 are each believed to provide better force distribution and lateral movement during one or more operations. The peninsulas 420 further have at least one mask opening 414 formed therein.

The frame 404 is connected to a plurality of microactuators 418. The microactuators 418 can be connected by a semi-permanent method, such as by welding. The microactuators 418 are each connected to a mask opening 414 formed in the peninsulas 420 on the fine metal mask 402, such that they stretch and shift the fine metal mask 402 as needed or desired.

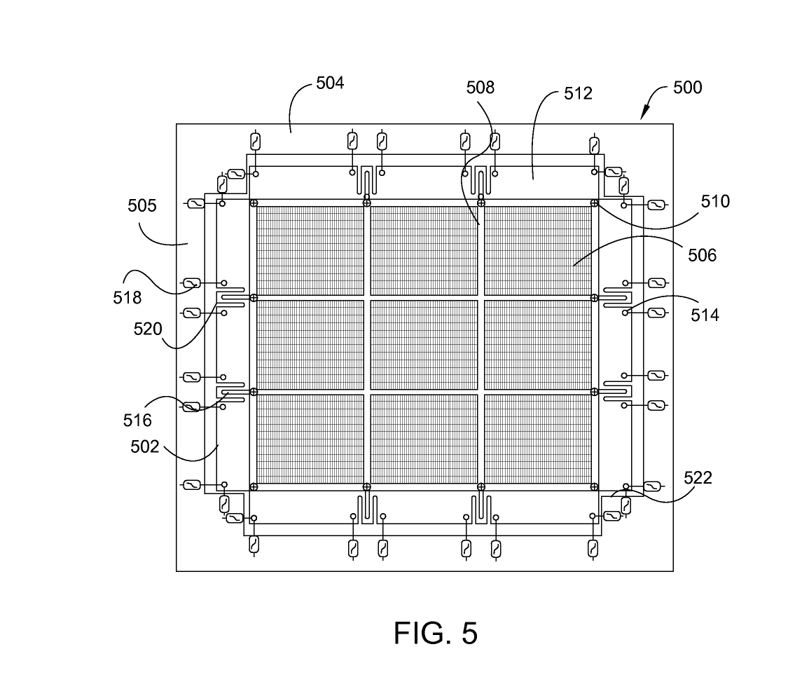

FIG. 5 depicts a mask assembly 500 according to another embodiment. The mask assembly 500 includes fine metal mask 502 and a frame 504. As described above, the fine metal mask 502 has a pattern 506, one or more streets 508 and a plurality of alignment marks 510 formed therein. As described in reference to FIG. 4, a connection plate 512 is formed around the pattern 506 with one or more peninsulas 520 formed therein. The peninsulas 520 each have at least one notch 516. In this embodiment, one or more mask openings 514 are formed around the peninsulas 520 in the connection plate 512.

The frame 504 can have a plurality of walls 505 and a plurality of internal corners 522, which act together to form a periphery around the fine metal mask 502. Depicted here, the frame 504 has four walls 505 and four internal corners 522 formed at the intersection of the walls 505. The frame 504 further has a plurality of microactuators 518 connected both at the walls and the internal corners 522 of the frame 504. The plurality of microactuators 518 are connected to at least one mask opening 514. Depicted here, each of the microactuators 518 can be connect between one of the mask openings 514 and one of the walls 505 of the frame 504. At the internal corners 522, two microactuators 518 can connect with each of the mask openings 514. Though depicted here as forming a 90 degree angle between the microactuators 518 as connected to the mask openings 514, other angles are possible.

The microactuators 518 are connected to the fine metal mask 502 through mask openings 514 which are formed one either side of the streets 508. Lateral directionality of this embodiment is controlled at the internal corners 522. Microactuators 518 can be formed at the internal corners 522 such that the fine metal mask 502 can be manipulated in any direction. Shown here, an internal corner 522 is formed on the frame 504 with two microactuators 518 connected to the internal corner 522 and two microactuators 518 connected to the frame 504. The four microactuators 518, in two sets of two, are connected perpendicularly to the fine metal mask 502 at one of the mask openings 514. By modulating the force applied to one or more of the microactuators 518 at the internal corner 522, the fine metal mask 502 can be stretched or shifted in any direction.

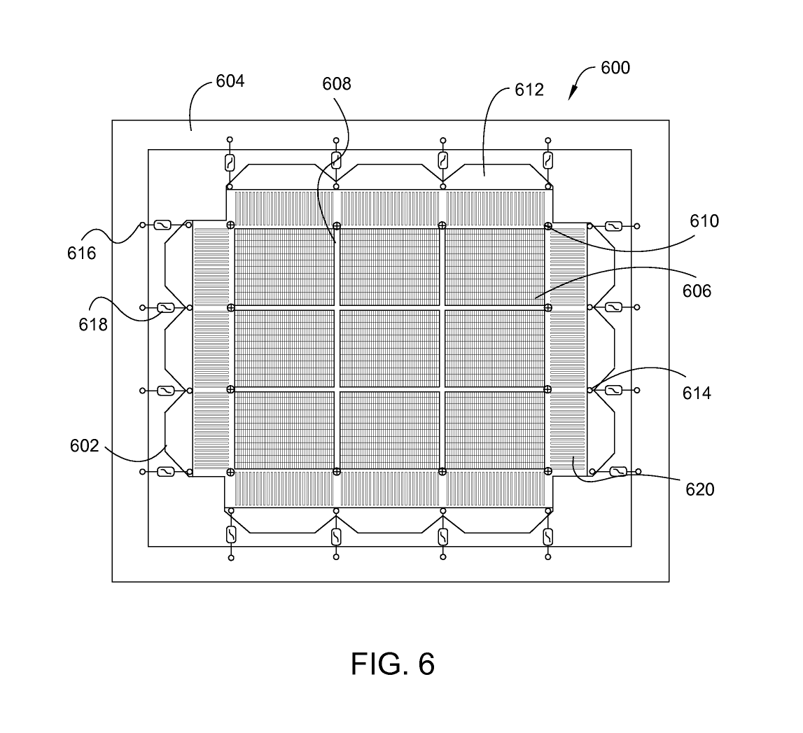

FIG. 6 depicts a mask assembly 600 according to another embodiment. The mask assembly 600 includes fine metal mask 602 and a frame 604. As described above, the fine metal mask 602 has a pattern 606, one or more streets 608, a plurality of mask openings 614 and a plurality of alignment marks 610 formed therein. In this embodiment, the mask openings 614 are formed at the streets 608. Formed in the fine metal mask 602, between the pattern 606 and one or more connection plates 612, are one or more slot formations 620. The slot formations 620 can allow for rigid connections between one or more connection plates 612 and the pattern 606 while allowing freedom of motion perpendicular to the slot formations 620, between the slot formations 620 and the pattern 606. Further, the slot formations 620 can allow the two orthogonal sets of microactuators 618 to tension/stretch the fine metal mask 602 in both directions. Using the slot formations 620, two orthogonal sets of microactuators 618 can tension/stretch the fine metal mask 602 despite the fact that the mechanical connection between the individual microactuators 618 and the fine metal mask 602 are effectively inextensible and few in number, such as less than approximately ten (10). In the embodiment described above, the microactuators in combination with the slot formations 620 can effectively tension or stretch the fine metal mask 602 through the microactuators 618 span a substantial portion of the edge of the fine metal mask 602 upon which they are pulling.

Formed in the frame 604 are pluralities of frame openings 616. The microactuators 618 can be connected to the frame 604 through the plurality of frame openings 616 and to the fine metal mask 602 through the plurality of mask openings 614. Thus, the frame 604 can be connected with the fine metal mask 602, at least in part, using a plurality of microactuators 618. Depicted here, the frame 604 and the fine metal mask 602 are connected using a single microactuator 618 at each mask opening 614 and at each frame opening 616. Though a single microactuator 618 is shown at each connection, the positioning or number of microactuators 618 used is not intended to be limiting.

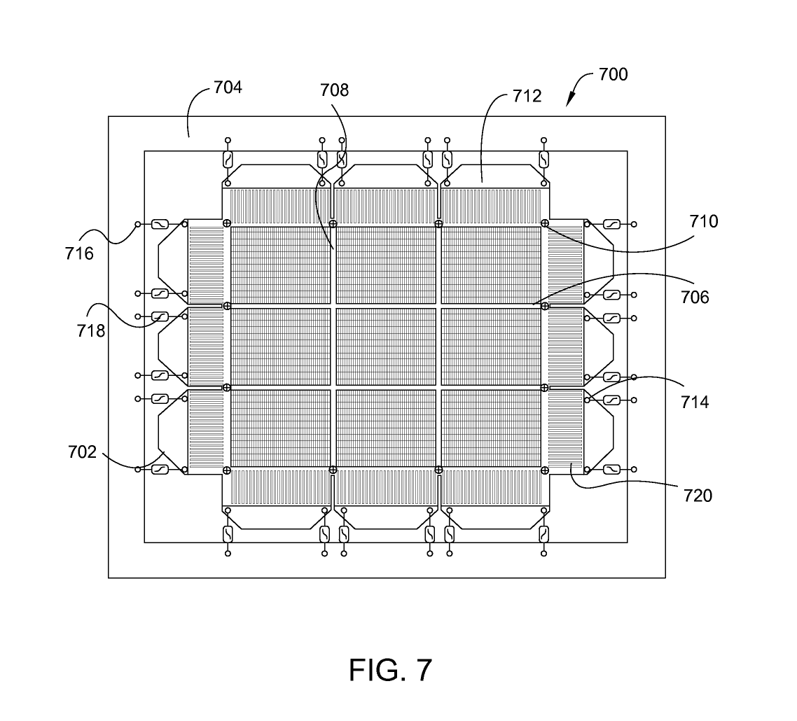

FIG. 7 depicts a mask assembly 700 according to another embodiment. The mask assembly 700 includes fine metal mask 702 and a frame 704. As described above, the fine metal mask 702 has a pattern 706, one or more streets 708, a plurality of alignment marks 710, a connection plate 712 and a plurality of mask openings 714 formed therein. A plurality of mask openings 714 are formed in the connection plate 712 of the fine metal mask 702. The frame 704 can include a plurality of frame openings 716. As described above, the frame openings 716 can connect with one or more microactuators 718, thus connecting the frame 704 to the fine metal mask 702.

In this embodiment, the mask openings 714 are formed around the street 708, thus creating two mask openings 714 for each street 708. Further, the street 708 is extended in this embodiment from the pattern 706 to the connection plate 712. This is believed to allow for independent control of the slot formations 720 based on the positioning of the microactuators 718 which may allow for better lateral control and more precise tensioning of the fine metal mask 702. The slot formations 720 can provide a substantially similar benefit to the slot formations 620 described with reference to FIG. 6.

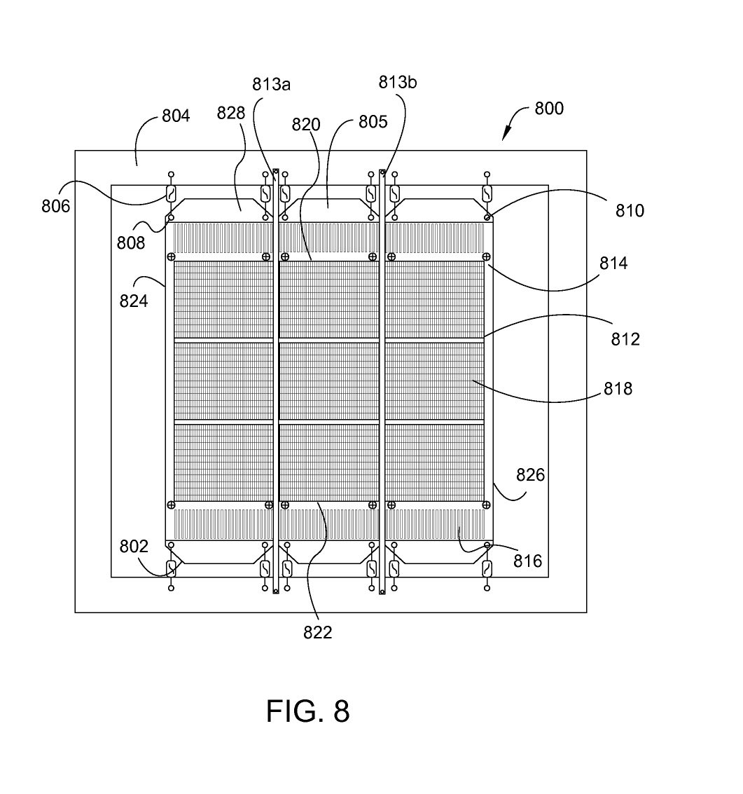

FIG. 8 depicts a dynamic strip mask device 800 according to another embodiment. The dynamic strip mask device 800 includes a frame 804 in connection with a fine metal mask 802. The fine metal mask 802 can have a connection plate 805 formed at the edge of the fine metal mask 802, such as being formed at one or more borders of a pattern 818. The connection plate 805 can have one or more mask openings 810 formed therein. The connection plate 805 can be formed on a single side or a single portion of the fine metal mask 802. Shown here, the connection plates 805 are formed on a first border 820 and a second border 822 of the fine metal mask 802. On a third border 824 and a fourth border 826, mask openings 810 are formed in one or more streets 812 of the fine metal mask 802. Formed between the connection plate 805 and the pattern 818 can be a slot formation 816. As depicted here, the slot formation 816 can be omitted from one or more portions of the fine metal mask 802, such as where the connection plate 805 is not used.

Connecting the fine metal mask 802 and the frame 804 are one or more microactuators 806. The microactuators 806 are connected to the mask connectors 810 at one end and to the frame 804 at the other end through one or more frame connectors 808. As shown here, the third border 824 and the fourth border 826 are connected with two microactuators 806 on each border. These microactuators 806 can help adjust the alignment of the fine metal mask 802. The first border 820 and the second border 822 are connected through the mask connectors 810 formed in the connection plates 805 to the frame connectors 808 of the frame 804. Shown here, six microactuators 806 connect the fine metal mask 802 on each of the first border 820 and the second border 822. Thus, the microactuators 806 on the first border 820 and the second border 822 can both adjust the position of and stretch the fine metal mask 802. In operation, the position and orientation of the fine metal mask 802 can be determined using one or more alignment marks 814. The microactuators 806 can use a determined position of the fine metal mask 802 based on the detected alignment marks 814 to then adjust the position of the fine metal mask 802 and stretch the fine metal mask 802 as necessary, prior to deposition.

The fine metal mask 802 can include one or more strips 828. The strips 828 are independently mobile portions of the fine metal mask 802, depicted here as three rectangle shaped strips 828. As described from the frame 804, positioned as shown in FIG. 8, the strips 828 of the fine metal mask 802 can be positioned either longitudinally or latitudinally, such that they can be adjusted and stretched in the corresponding directions. Shown here, the strips 828 are positioned in a longitudinal direction. Further, the strips 828 can be adjusted, stretched or reoriented independent of one another, such that the deposition profile under each of the strips 828 is corrected independently of one another. In one example, the strips 828 are only aligned over the current deposition area, based on the position of the deposition head. The strips 828 shown here are intended to be exemplary of possible embodiments and are not intended to be limiting. In further examples, the strips 828 can be of different shapes and sizes, or be positioned such that they may be stretched in any direction.

The gaps between the strips 828 can be covered by blocking pieces 813a and 813b. The blocking pieces 813a and 813b can be composed of the same material as the fine metal mask 802. The blocking pieces 813a and 813b have dimensions which allow the blocking piece to prevent deposition on a substrate 102 from the source 108 through the gaps between the strips 828 while not interfering with other deposition or damaging the substrate 102 due to contact. Though shown here as two blocking pieces 813a and 813b, there may be more or fewer blocking pieces to accommodate for an increased or decreased number of strips 828 or as the user desires.

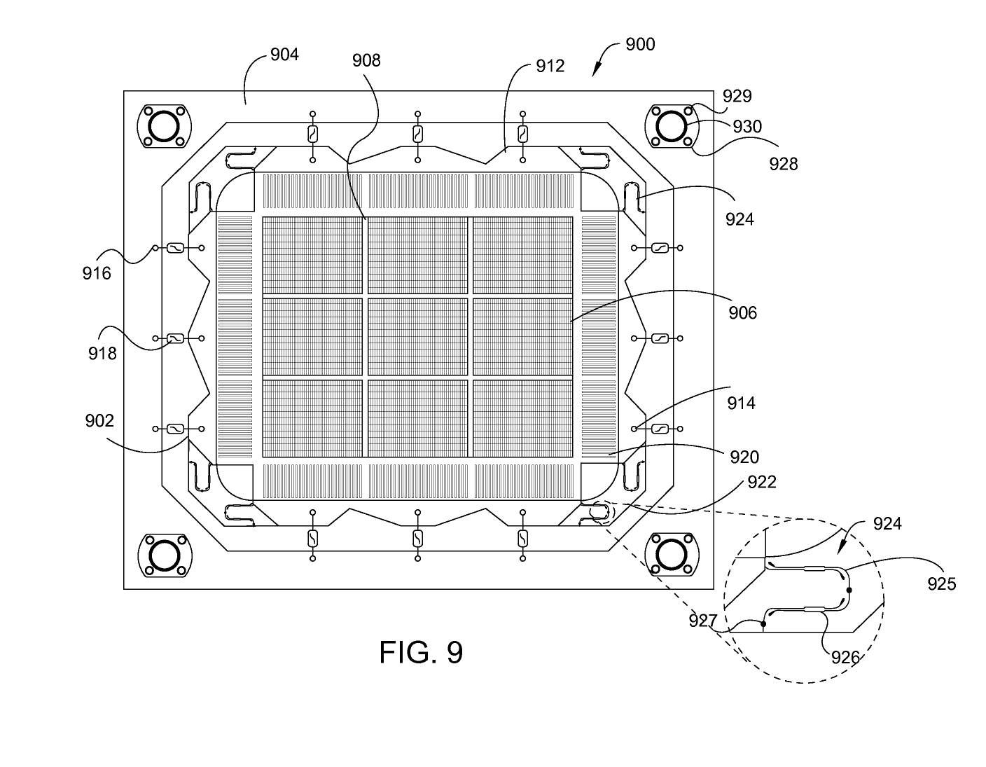

FIG. 9 depicts a mask assembly 900 according to another embodiment. The mask assembly 900 includes fine metal mask 902 and a frame 904. As described above, the fine metal mask 902 has a pattern 906, one or more streets 908, and a plurality of mask openings 914 formed therein. Formed in the fine metal mask 902, between the pattern 906 and one or more connection plates 912, are the one or more slot formations 920. The slot formations 920 can perform a substantially similar effect to the slot formations 620 described with reference to FIG. 6. A plurality of microactuators 918 are connected with the fine metal mask 902 through the connection plates 912.

The fine metal mask 902 further includes a plurality of connection arms 922. Each of the connection arms 922 are formed between adjacent connection plates 912. The connection arms 922 can be substantially L shaped as shown or include other shapes such that the connection arms 922 contact at least two adjacent connection plates 912. In one embodiment, the connection plates 912 and connection arms 933 comprise a unitary piece of material. The connection arms 922 have at least one movement control formation 924. The movement control formation 924 reduces the movement of the connection plate 912 to two directions which follow the direction of force applied by the connected microactuators 918.

The movement control formation 924 includes a plurality of movement slits 925. The movement slits 925 are a separation between two adjacent walls which creates a space for movement in the otherwise immobile connection arm 922. Thus, the movement slits 925 control both the direction of the movement and the distance of the movement, as the fine metal mask con only move the distance created by the width of the movement slits 925. Further, the movement slits 925 create space in the connection arm 922 which allows each side of the connection arm 922 to move in two directions without disconnecting. The notches 926 prevent forces in undesired directions from separating the adjacent portions of the connection arm 924. The insert holes 927 can receive an insert (not shown), such as a screw, a pin or other object. The object, when positioned in the insert holes 927, will then prevent the movement allowed by the movement control formation 924.

It is believed that the microactuators 918 can provide force to the fine metal mask 902 simultaneously which changes the direction of the force and can lead to a shearing effect on or other damage to the fine metal mask 902. By restricting the movement caused by the microactuators 918 to two directions using the movement control formation 924, this cumulative shearing effect or other tension related damage can be avoided.

Formed in the frame 904 are pluralities of frame openings 916. The microactuators 918 can be connected to the frame 904 through the plurality of frame openings 916 and to the fine metal mask 902 through the plurality of mask openings 914. Thus, the frame 904 can be connected with the fine metal mask 902, at least in part, using a plurality of microactuators 918. Depicted here, the frame 904 and the fine metal mask 902 are connected using a single microactuator 918 at each mask opening 914 and at each frame opening 916. Though a single microactuator 918 is shown at each connection, the positioning or number of microactuators 918 used is not intended to be limiting.

In connection with the frame 904 are a plurality of fine adjustment actuators 928. The fine adjustment actuators 928 each have a plurality of magnets 929 which can connect to the substrate support (not shown). The plurality of magnets can be any type of magnet capable of attaching to a ferromagnetic substance. The fine adjustment actuators 928 then use detectors 930 to control the distance of the frame 904 and the fine metal mask 902 from the substrate support.

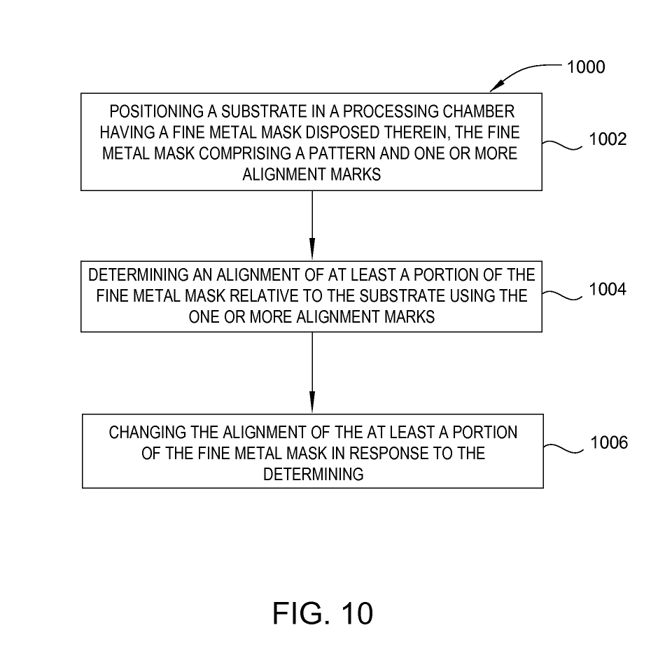

FIG. 10 is a block diagram of a method 1000 for adjusting a fine metal mask according to one embodiment. The actively aligned fine metal masks described above can be positioned in the processing chamber in connection with a substrate. Based on temperature, position of the deposition head and other factors, at least a portion of the fine metal mask can be aligned and stretched. Once properly aligned and stretched, the fine metal mask can be positioned in connection with the substrate for deposition.

The method 1000 includes positioning a substrate in a processing chamber having a fine metal mask disposed therein, the fine metal mask comprising a pattern and one or more alignment marks, as in 1002. The substrate can be a substrate as described with reference to FIGS. 1A and 1B. The fine metal mask, including the pattern and the alignment marks, can be a fine metal mask as described with reference to FIGS. 1B-9, including combinations of characteristics or features described therein.

The method 1000 further includes determining an alignment of at least a portion of the fine metal mask relative to the substrate using the one or more alignment marks, as in 1004. Alignment marks can be positioned at various locations on the surface of the fine metal mask, such as in the streets and in the connection plate, as depicted in FIGS. 1B-9. An optical system is then applied to determine the position of the alignment mark in comparison to a set point in the processing chamber, such as the substrate. The position of the fine metal mask in comparison to the substrate is then extrapolated from the determined position of the alignment marks.

The method 1000 further includes changing the alignment of the at least a portion of the fine metal mask in response to the determining, as in 1006. Using the determined position of the fine metal mask, the fine metal mask is stretched or adjusted such that at least the portion of the fine metal mask which is currently being used for deposition, is in alignment with the substrate. In one embodiment, the entire fine metal mask is positioned in alignment with the substrate. In another embodiment, a specific strip of the fine metal mask is aligned without aligning other components of the mask.

Once the fine metal mask is aligned, the fine metal mask can be positioned in connection with the substrate such that the deposition head can deposit through the mask to the substrate. At this point, the fine metal mask can be realigned for the next portion of the deposition until the deposition process is complete.

Changing the alignment of the fine metal mask, as stated above, does not require that the whole fine metal mask be adjusted. In one embodiment, the entire fine metal mask is aligned based on the determined position of the alignment marks, with all portions of the pattern correctly positioned and adjusted over the respective portion of the substrate. The source can then deposit through each portion of the fine metal mask in a predetermined order, which may be sequentially.

In another embodiment, the alignment of the fine metal mask is adjusted at a specific region, such as one of the squares shown as nine squares in the pattern of FIGS. 1B-9. A first square or portion of the pattern is properly adjusted, such that the source can deposit on the substrate through the first square or portion, without consideration of other areas. The first square or portion can be selected from any location on the pattern. Adjusting the first square or portion may require any number of the microactuators applying force to the fine metal mask with some microactuators applying more force than others, such as movement at a single microactuator, a few microactuators or all microactuators. Once the deposition is complete at the first square or portion, the source scans to the second square or portion of the fine metal mask, while the fine metal mask is adjusted at the second square or position. The second square or portion can be at any portion of the pattern and can be non-linear as compared to the first square or portion. The second square or portion of the pattern is properly adjusted, such that the source can deposit on the substrate through the second square or portion, without consideration of other areas.

In another embodiment, the alignment of the fine metal mask is aligned at a specific strip without aligning other strips. The strips, shown in FIG. 8, can be separately aligned such that the corresponding portion of the fine metal mask is aligned with the substrate. Once aligned, the source can deposit through the aligned strip or a portion thereof, before moving to the next portion of the strip or strip of the fine metal mask. In this case, the strips are aligned independently which allows for reduced stress on other portions of the fine metal mask while achieving high resolution deposition on the substrate.

Below is listed parameters related to one or more materials which can be used in the embodiments described herein. The parameters described below are for a fine metal mask of one or more of the designs above, with a length of 2.5 meters, a width of 2 meters, a thickness of 100 μm and a section area of 200 mm² per section.

The first example is INVAR, which has a coefficient of thermal expansion (CTE) of 1.3 μm/m° C., a yield strength of 70 ksi, and a Young's modulus of 21500 ksi. With a temperature rise of 50° C., the thermal expansion is 162.5 μm. The strain and stress necessary to correct for the expansion is 0.0065% and 1.398 ksi. Thus, in embodiments which employ 16 actuators, a force per actuator of 27.1 lbs is required.

The second example is Ti-6Al-4V, which has a CTE of 8.6 μm/m° C., and a yield strength of 128 ksi, and a Young's modulus of 16510 ksi. With a temperature rise of 50° C., the thermal expansion is 1075 μm. The strain and stress necessary to correct for the expansion is 0.043% and 7.099 ksi. Thus, in embodiments which employ 16 actuators, a force per actuator of 137.5 lbs is required.

The third example is titanium, which has a CTE of 8.9 μm/m° C., a yield strength of 20.3 ksi, and a Young's modulus of 16800 ksi. With a temperature rise of 50° C., the thermal expansion is 1112.5 pm. The strain and stress necessary to correct for the expansion is 0.0445% and 7.476 ksi. Thus, in embodiments which employ 16 actuators, a force per actuator of 144.8 lbs is required.

The fourth example is Al 5xxx-0, which has a CTE of 23 μm/m° C., a yield strength of 22 ksi, and a Young's modulus of 10000 ksi. With a temperature rise of 50° C., the thermal expansion was 2875 μm. The strain and stress necessary to correct for the expansion is 0.115% and 11.500 ksi. Thus, in embodiments which employ 16 actuators, a force per actuator of 222.8 lbs is required.

The fifth example is molybdenum, which has a CTE of 5.35 μm/m° C., a yield strength of 60.2 ksi, and a Young's modulus of 47900 ksi. With a temperature rise of 50° C., the thermal expansion was 668.75 μm. The strain and stress necessary to correct for the expansion is 0.0268% and 12.813 ksi. Thus, in embodiments which employ 16 actuators, a force per actuator of 248.3 lbs is required.

The sixth example is copper, which has a CTE of 16.4 μm/m° C., a yield strength of 4.3 ksi, and a Young's modulus of 16000 ksi. With a temperature rise of 50° C., the thermal expansion was 2050 μm. The strain and stress necessary to correct for the expansion is 0.082% and 13.120 ksi. Thus, in embodiments which employ 16 actuators, a force per actuator of 254.2 lbs is required.

The seventh example is 440 stainless steel, which has a CTE of 10.2 μm/m° C., a yield strength of 168 ksi, and a Young's modulus of 29000 ksi. With a temperature rise of 50° C., the thermal expansion was 1275 μm. The strain and stress necessary to correct for the expansion is 0.051% and 14.790 ksi. Thus, in embodiments which employ 16 actuators, a force per actuator of 286.6 lbs is required.

The eighth example is HASTELLOY® alloy C-276, which has a CTE of 11.2 μm/m° C., a yield strength of 29.7 ksi, and a Young's modulus of 29700 ksi. With a temperature rise of 50° C., the thermal expansion was 1400 μm. The strain and stress necessary to correct for the expansion is 0.056 and 16.632 ksi. Thus, in embodiments which employ 16 actuators, a force per actuator of 322.2 lbs is required.

The ninth example is nickel, which has a CTE of 13 μm/m° C., a yield strength of 15 ksi, and a Young's modulus of 29300 ksi. With a temperature rise of 50° C., the thermal expansion was 1625 pm. The strain and stress necessary to correct for the expansion is 0.065% and 19.045 ksi. Thus, in embodiments which employ 16 actuators, a force per actuator of 347.3 lbs is required.

The tenth example is chrome-molybdenum steel, which has a CTE of 12.1 μm/m° C., a yield strength of 150 ksi, and a Young's modulus of 30000 ksi. With a temperature rise of 50° C., the thermal expansion was 1512.5 pm. The strain and stress necessary to correct for the expansion is 0.0605% and 18.150 ksi. Thus, in embodiments which employ 16 actuators, a force per actuator of 351.7 lbs is required.

The eleventh example is 440 stainless steel, which has a CTE of 17.3 μm/m° C., a yield strength of 31.2 ksi, and a Young's modulus of 28500 ksi. With a temperature rise of 50° C., the thermal expansion was 2162.5 pm. The strain and stress necessary to correct for the expansion is 0.0865% and 24.653 ksi. Thus, in embodiments which employ 16 actuators, a force per actuator of 477.6 lbs is required.

Embodiments disclosed herein relate to active alignment of a fine metal mask. As the fine metal mask and the substrate heat up, they expand with relation to their coefficient of thermal expansion. As the coefficients are different between the materials, the alignment between the fine metal mask and the substrate becomes offset over time. By connecting the fine metal mask to a rigid frame through a plurality of microactuators, the fine metal mask can be positioned and shaped with relation to the substrate. The actively positioned fine metal mask can produce a more precise deposition product.

While the foregoing is directed to embodiments of the invention, other and further embodiments of the invention may be devised without departing from the basic scope thereof.

1. A masking device, comprising:
a fine metal mask having a pattern and a connection plate surrounding the pattern; and
a plurality of microactuators coupled to the fine metal mask.

2. The device of claim 1, wherein the microactuators are coupled to the connection plate.

3. The device of claim 1, wherein the fine metal mask has a plurality of mask openings.

4. The device of claim 1, wherein two or more microactuators are coupled to the fine metal mask at a single mask opening.

5. The device of claim 1, further comprising a slot formation comprising plurality of parallel slots formed between the connection plate and the pattern.

6. The device of claim 1, wherein the fine metal mask comprises a plurality of strips.

7. The device of claim 6, further comprising a slot formation comprising plurality of parallel slots formed between the connection plate and the pattern.

8. A masking device, comprising:
a frame comprising a plurality of frame openings formed on at least one side of the frame;
a fine metal mask, comprising:
at least one pattern;
a connection plate formed on at least one side of the pattern; and
one or more mask openings therethrough; and
a plurality of actuators coupled to:
the frame; and
the fine metal mask.

9. The device of claim 8, wherein the microactuators are coplanar with the first metal mask and the frame.

10. The device of claim 8, wherein a plurality of peninsulas are formed in the connection plate.

11. The device of claim 10, wherein each peninsula further comprises a notch formed therein.

12. The device of claim 8, wherein the fine metal mask and the frame are connected using two or more microactuators, the microactuators connecting with the fine metal mask at a single mask opening.

13. The device of claim 8, further comprising a slot formation formed between the pattern and the connection plate.

14. The device of claim 8, further comprising a frame peninsula formed in the frame and extending toward the fine metal mask.

15. The device of claim 14, wherein the connection plate is shaped to receive the frame peninsula.

16. The device of claim 8, wherein the frame further comprises an internal corner.

17. The device of claim 16, wherein at least one of the plurality of actuator coupled to both the internal corner and the fine metal mask.

18. A method of adjusting a mask, comprising:
positioning a substrate in a processing chamber having a fine metal mask disposed therein, the fine metal mask comprising:
a pattern; and
one or more alignment marks;
determining an alignment of at least a portion of the fine metal mask relative to the substrate using one or more alignment marks; and
changing the alignment of the at least a portion of the fine metal mask response to the determining.

19. The method of claim 18, wherein the fine metal mask further comprises or or more microactuators.

20. The method of claim 19, wherein changing the desired alignment comprises activating at least one of the microactuators.
